(19) United States
(12) Patent Application Publication
(10) Pub. No.: US 2021/0336231 A1
(43) Pub. Date: Oct. 28, 2021

(54) DISPLAY PANEL AND ELECTRONIC DEVICE

(71) Applicant: WUHAN CHINA STAR OPTOELECTRONICS SEMICONDUCTOR DISPLAY TECHNOLOGY CO., LTD., Wuhan, Hubei (CN)

(72) Inventor: Xing WANG, Wuhan, Hubei (CN)

(21) Appl. No.: 16/605,033

(22) PCT Filed: Jul. 22, 2019
(86) PCT No.: PCT/CN2019/096965

§ 371 Date: Oct. 14, 2019

(30) Foreign Application Priority Data
Apr. 17, 2019 (CN) 201910309844.7

(51) Int. Cl. H01L 51/52

(52) U.S. Cl. CPC H01L 51/5284; H01L 27/3262; H01L 51/5218

(57) ABSTRACT

A display panel and an electronic device. The display panel includes a substrate and a display region and a transparent display region disposed on the substrate; wherein the transparent display region includes a first anode, a first pixel defining layer, the first pixel defining layer including a first opening exposing the first anode, a first light emitting material disposed on the first anode, a first cathode disposed on the first light emitting material, and a dimming layer disposed on the first anode.

### BACKGROUND OF INVENTION

### Field of Invention

The present invention relates to the field of display technologies, and in particular, to a display panel and an electronic device.

### Description of Prior Art

In order to achieve full-screen display in smart devices, the latest smart devices integrate cameras under display panels. The display panels above the cameras are configured with an electronic display function and a light transmission function. As shown in FIG. 1 and FIG. 2, taking a smartphone as an example, a display panel of the smartphone includes an imaging area 010 and an operation area 012, and a position of the imaging area 010 corresponds to a camera 011 disposed below the display panel. The display panel 012 includes a flexible substrate 0121, a thin film transistor layer 0122, a light emitting layer 0123, an encapsulation layer 0124, a touch layer 0125, and a glass cover 0126.

### Technical Problems

The thin film transistor layer 0122 contains a large number of metal traces, and the metal traces can reflect natural light, which affects imaging quality of the camera. Therefore, this phenomenon needs to be improved.

### SUMMARY OF INVENTION

The present application provides a display panel and an electronic device to eliminate reflection of natural light by a display panel.

In order to solve the above problems, the present application provides a display panel, wherein the display panel comprises a substrate and a display region and a transparent display region disposed on the substrate;

wherein the transparent display region comprises:

a first anode;

a first pixel defining layer, the first pixel defining layer including a first opening exposing the first anode;

a first light emitting material disposed on the first anode;

a first cathode disposed on the first light emitting material; and

a dimming layer disposed on the first anode;

wherein the dimming layer is a Bragg film.

According to one aspect of the application, wherein the dimming layer is disposed between the first anode and the first pixel defining layer or on the first cathode.

According to one aspect of the application, wherein the dimming layer comprises a transparent opening disposed corresponding to the first opening.

According to one aspect of the application, wherein the display region comprises:

a second anode;

a second pixel defining layer, the second pixel defining layer including a second opening exposing the second anode;

a second light emitting material disposed on the second anode;

a second cathode disposed on the second light emitting material;

wherein the second cathode is electrically insulated from the first cathode.

The display panel according to claim 1, wherein the Bragg film comprises a first film and a second film which are alternately laminated, materials of the first film and the second film are different, and a refractive index of the first film is greater than a refractive index of the second film.

According to one aspect of the application, wherein the first film is silicon, and the second film is one of silicon oxide, aluminum oxide, and titanium oxide.

According to one aspect of the application, wherein the first light emitting material is disposed in the first opening and is electrically connected to the first anode; the dimming layer is disposed between the first pixel defining layer and the first cathode.

The present application further provides a display panel, wherein the display panel comprises a substrate and a display region and a transparent display region disposed on the substrate;

wherein the transparent display region comprises:

a first anode;

a first pixel defining layer, the first pixel defining layer including a first opening exposing the first anode;

a first light emitting material disposed on the first anode;

a first cathode disposed on the first light emitting material; and

a dimming layer disposed on the first anode.

According to one aspect of the application, wherein the dimming layer is disposed between the first anode and the first pixel defining layer or on the first cathode.

According to one aspect of the application, wherein the dimming layer comprises a transparent opening disposed corresponding to the first opening.

According to one aspect of the application, wherein the display region comprises:

a second anode;

a second pixel defining layer, the second pixel defining layer including a second opening exposing the second anode;

a second light emitting material disposed on the second anode;

a second cathode disposed on the second light emitting material;

wherein the second cathode is electrically insulated from the first cathode.

According to one aspect of the application, wherein the dimming layer is a Bragg film.

According to one aspect of the application, wherein the Bragg film comprises a first film and a second film which are alternately laminated, materials of the first film and the second film are different, and a refractive index of the first film is greater than a refractive index of the second film.

According to one aspect of the application, wherein the first film is silicon, and the second film is one of silicon oxide, aluminum oxide, and titanium oxide.

According to one aspect of the application, wherein the first light emitting material is disposed in the first opening and is electrically connected to the first anode; the dimming layer is disposed between the first pixel defining layer and the first cathode.

The present application further provides an electronic device, wherein the electronic device comprises a display panel and a light sensing unit disposed under the display panel, the display panel comprises a substrate and a display region and a transparent display region disposed on the substrate;

wherein the transparent display region comprises:

a first anode;

a first pixel defining layer, the first pixel defining layer including a first opening exposing the first anode;

a first light emitting material disposed on the first anode;

a first cathode disposed on the first light emitting material; and

a dimming layer disposed on the first anode.

According to one aspect of the application, wherein the dimming layer is a Bragg film.

According to one aspect of the application, wherein a projection of the light sensing unit on a horizontal plane overlaps with a projection of the transparent display region on a horizontal plane.

Beneficial Effects

The present application forms a dimming layer in the light transparent region of the display panel, a projection of the dimming layer on the first anode covers a first anode disposed below the first pixel defining layer and separates from a first anode disposed below the first opening. Thereby, light reflected by the anode metal can be eliminated, reflection ability of metal trace of the transparent region to the natural light is reduced, and the imaging quality of the camera is improved.

### BRIEF DESCRIPTION OF DRAWINGS

FIG. 1 is a structural diagram of a display panel of a smart device in the prior art.

FIG. 2 is a cross-sectional view of FIG. 1 taken along the line AN.

FIG. 3 to FIG. 5 are structural diagrams of a display panel in different process steps of a specific embodiment of the present application.

FIG. 6 is a structural diagram of a display panel in another embodiment of the present application.

FIG. 7 is a structural diagram of a display panel in a third embodiment of the present application.

FIG. 8 is a structural diagram of a Prague film in a specific embodiment of the present application.

FIG. 9 is a plan view of a transparent display region of a display panel in an embodiment of the present application.

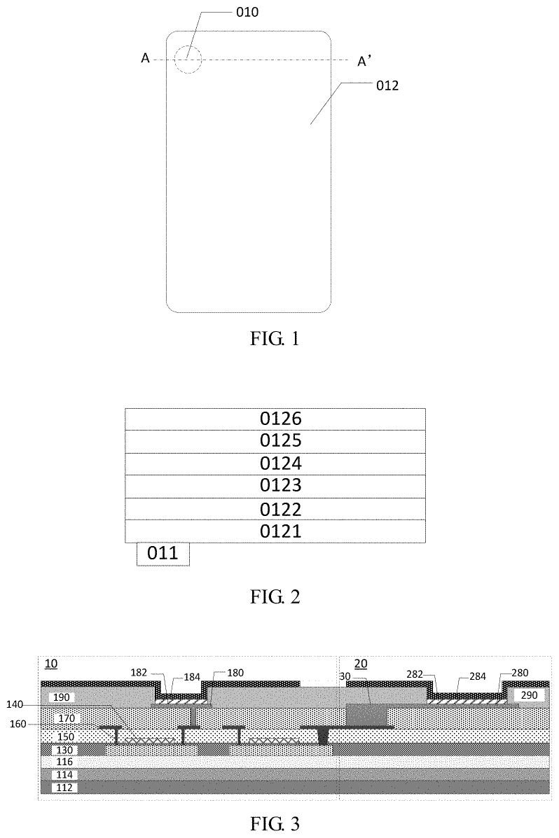

### DETAILED DESCRIPTION OF PREFERRED EMBODIMENTS

Description of following embodiment, with reference to accompanying drawings, is used to exemplify specific embodiments which may be carried out in the present disclosure. Directional terms mentioned in the present disclosure, such as “top”, “bottom”, “front”, “back”, “left”, “right”, “inside”, “outside”, “side”, etc., are only used with reference to orientation of the accompanying drawings. Therefore, the directional terms are intended to illustrate, but not to limit, the present disclosure. In the drawings, components having similar structures are denoted by same numerals.

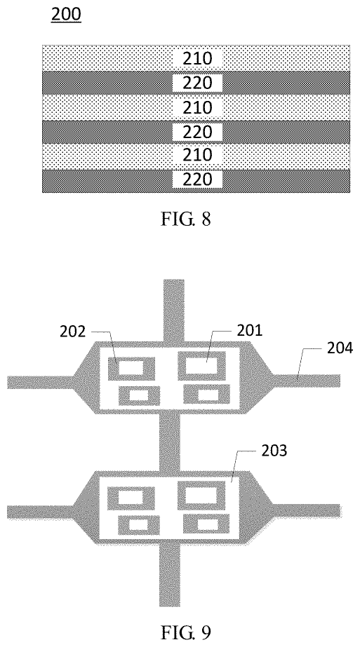

In order to eliminate reflection of natural light by the display panel above the camera, the present application provides a display panel, which will be described in detail below in conjunction with specific embodiments. Referring to FIG. 5 and FIG. 9, FIG. 5 is a structural diagram of a display panel in a specific embodiment of the present application, FIG. 9 is a plan view of a transparent display region of a display panel in an embodiment of the present application.

In this embodiment, the display panel includes a substrate and a display region 10 and a transparent display region 20 on the substrate.

Referring to FIG. 5, the substrate includes a driving circuit and a planarization layer 170, the planarization layer 170 covers the driving circuit and has a plurality of via holes exposing metal trace of the driving circuit. Specifically, the driving circuit includes an insulating substrate, an active region on the insulating substrate, the active region including a channel region and a source region and a drain region respectively located on both sides of the channel region, a gate dielectric layer 130 covering the active region, a gate metal 140 on the gate dielectric layer 130 and covering the channel region, a interlayer dielectric layer 150 covering the gate metal 140, a source/drain trace 160 penetrating the interlayer dielectric layer 150 and electrically connected to the source region and drain region.

The insulating substrate includes a substrate 112, an encapsulation structure 114 disposed on the substrate, and a buffer layer 116 disposed on the sealing structure 114.

The transparent display region 20 includes a first anode 280 disposed on the planarization layer 170 and electrically connected to the driving circuit through the via hole, a first pixel defining layer 190 covering the planarizing layer 170 and the first anode 280 and having a first opening exposing the first anode 280, a first light emitting material 282 disposed on the first anode 280 and electrically connected to the first anode 280, a first cathode 284 disposed on the first light emitting material 282, and a dimming layer 286 disposed on the first anode 280.

The display region includes a second anode 180, a second pixel defining layer 190 including a second opening exposing the second anode 180, a second light emitting material 182 disposed on the second anode 180, a second cathode 184 disposed on the second light emitting material 182, the second cathode 184 is electrically insulated from the first cathode 284.

In the prior art, the first cathode and the second cathode are metal layers simultaneously formed by a full-surface vapor deposition process. Metal layers have a strong shielding effect on light, which affects the transparent effects of the transparent display region. In order to solve this defect, as shown in FIG. 5, in the embodiment, the second cathode 184 is electrically insulated from the first cathode 284. Moreover, when the light emitting surface of the display panel is parallel to the horizontal plane, a projection of the first cathode 284 on a horizontal surface overlaps with a projection of the first anode 280 on the horizontal surface.

This design reduces the area in which the cathode of the transparent display region is disposed and enhances the light transmittance of the transparent display region. Further, the first cathode 284 can be formed using a transparent conductive material instead of a metal to further enhance the light transmittance of the transparent display region.

In this embodiment, the dimming layer includes a transparent opening disposed corresponding to the first opening. When a light emitting surface of the display panel is parallel to the horizontal plane, a projection of the transparent opening on the horizontal surface overlaps with a projection of the first opening on the horizontal surface. Because the dimming layer absorbs light, the transparent opening can prevent the dimming layer from affecting light emitted by the pixel unit.

The dimming layer 286 can be disposed between any two film layers above the second anode 280. As long as a projection of the dimming layer 286 on the first anode 280 covers the first anode 280 under the first pixel defining layer 190 and separates from the first anode 280 under the first opening, the attenuation and elimination of reflected light can be achieved.

As shown in FIG. 5, in the embodiment, the dimming layer 286 is located on the first cathode 284. As shown in FIG. 6, FIG. 6 is a structural diagram of a display panel in another embodiment of the present application. The dimming layer 286 is located between the first pixel defining layer 190 and the first cathode 284. As shown in FIG. 7, FIG. 7 is a structural diagram of a display panel in a third embodiment of the present application. The dimming layer 286 is located between the first anode 280 and the first pixel defining layer 190.

In this embodiment, the dimming layer 286 is a Bragg film. Referring to FIG. 8, FIG. 8 is a structural diagram of a Bragg film in a specific embodiment of the present application. The Bragg reflection structure is a thin film structure formed by alternately laminating first film and second films, wherein the first films having a high refractive index and the second films having a low refractive index. Preferably, the first films and the second films have a same thickness ranging from 50 to 150 nm. The Prague film can effectively eliminate the light reflected by the anode, thereby reducing the light reflectance of the transparent display region.

In the present embodiment, the Bragg film includes first films 210 and second films 220 which are alternately laminated, and the materials of the first films 210 and the second films 220 are different. Specifically, a refractive index of the first film 210 is greater than a refractive index of the second film 220.

In this embodiment, the first film 210 is silicon, and the second film 220 is one of silicon oxide, aluminum oxide, and titanium oxide.

FIG. 9 is a plan view of a transparent display region of a display panel in an embodiment of the present application. The transparent display region includes a pixel region 201, an anode 202, a transparent region 203, and an anode trace 204. By adding a layer of Bragg film on the anode 202 and the anode trace 204 outside the pixel region 201, the reflection of the anode trace can be effectively eliminated.

Preferably, in this embodiment, the number of layers of the first films and the number of layers of the second films are both greater than 3.

In another embodiment of the present application, a projection of the transparent display region 20 on the substrate does not overlap with the driving circuit. The transparent display area 20 includes a connection trace, and one end of the connection trace is electrically connected to the driving circuit through the via hole, and the other end of the connection trace is electrically connected to the first anode 280.

Correspondingly, the present application also provides a method for manufacturing the display panel, which will be described in detail below with reference to the accompanying drawings.

First, referring to FIG. 3, a substrate is provided, the substrate including a driving circuit and a planarization layer 170 covering the driving circuit and having a plurality of via holes exposing metal trace in the driving circuit.

Specifically, the driving circuit includes an insulating substrate, an active region on the insulating substrate, the active region including a channel region and a source region and a drain region respectively located on both sides of the channel region, a gate dielectric layer 130 covering the active region, a gate metal 140 on the gate dielectric layer 130 and covering the channel region, a interlayer dielectric layer 150 covering the gate metal 140, a source/drain trace 160 penetrating the interlayer dielectric layer 150 and electrically connected to the source region and drain region.

Thereafter, a first anode 280 and a second anode 180 are formed on the planarization layer 170, and the first anode 280 and the second anode 180 are electrically connected to the driving circuit through the via holes.

Thereafter, a first pixel defining layer 190 covering the planarization layer 170 and the first anode 280 and a second pixel defining layer 290 covering the planarization layer 170 and the second anode 180 are formed. The first pixel defining layer 190 has a first opening exposing the first anode 280, and the second pixel defining layer 290 has a second opening exposing the second anode 180.

Then forming a first light emitting material 282 on the first anode 280 and a second light emitting material 182 on the second anode 180. The first light emitting material 282 is electrically connected to the first anode 280, and the second light emitting material 182 is electrically connected to the second anode 180.

Then forming a first cathode 284 and a second cathode 184 on the first light emitting material 282.

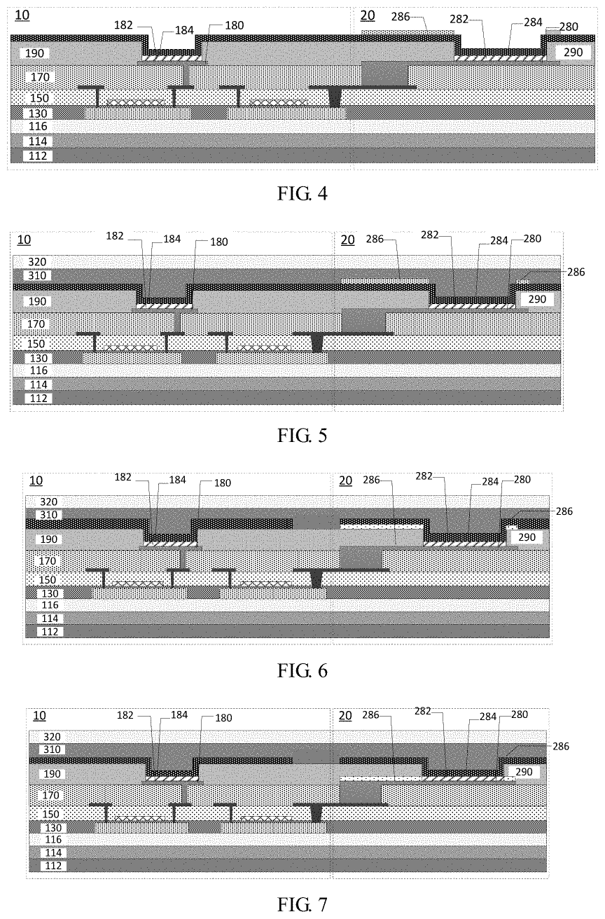

As shown in FIG. 4, after forming the first anode 280 and the second anode 180, the method further includes forming a dimming layer 286 disposed on the first anode 280. A projection of the dimming layer 286 on the first anode 280 covers the first anode 280 under the first pixel defining layer 190 and separates from the first anode 280 under the first opening. Specifically, the dimming layer 286 is a Bragg film.

Thereafter, as shown in FIG. 5, the method further includes forming a second planarization layer 310 and an encapsulation structure 320 covering the first cathode 284 and the second cathode 184.

The dimming layer 286 can be disposed between any two film layers above the second anode 280. As long as a projection of the dimming layer 286 on the first anode 280 covers the first anode 280 under the first pixel defining layer 190 and separates from the first anode 280 under the first opening, the attenuation and elimination of reflected light can be achieved.

As shown in FIG. 5, in the embodiment, the dimming layer 286 is located on the first cathode 284. As shown in FIG. 6, FIG. 6 is a structural diagram of a display panel in another embodiment of the present application. The dimming layer 286 is located between the first pixel defining layer 190 and the first cathode 284. As shown in FIG. 7, FIG. 7 is a structural diagram of a display panel in a third embodiment of the present application. The dimming layer 286 is located between the first anode 280 and the first pixel defining layer 190.

The present application further provides an electronic device, the electronic device comprises a display panel and a light sensing unit disposed under the display panel, the display panel comprises a substrate and a display region and a transparent display region disposed on the substrate. A projection of the light sensing unit on a horizontal plane overlaps with a projection of the transparent display region 20 on a horizontal plane. Specifically, the light sensing unit is a camera or other light sensing device, such as a screen fingerprint recognition unit.

The present application forms a dimming layer in the light transparent region of the display panel, a projection of the dimming layer on the first anode covers a first anode disposed below the first pixel defining layer and separates from a first anode disposed below the first opening. Thereby, light reflected by the anode metal can be eliminated, reflection ability of metal trace of the transparent region to the natural light is reduced, and the imaging quality of the camera is improved.

As is understood by persons skilled in the art, the foregoing preferred embodiments of the present disclosure are illustrative rather than limiting of the present disclosure. It is intended that they cover various modifications and that similar arrangements be included in the spirit and scope of the present disclosure, the scope of which should be accorded the broadest interpretation so as to encompass all such modifications and similar structures.

What is claimed is:

1. A display panel, wherein the display panel comprises a substrate and a display region and a transparent display region disposed on the substrate;
wherein the transparent display region comprises:
a first anode;
a first pixel defining layer, the first pixel defining layer including a first opening exposing the first anode;
a first light emitting material disposed on the first anode;
a first cathode disposed on the first light emitting material; and
a dimming layer disposed on the first anode;
wherein the dimming layer is a Bragg film.

2. The display panel according to claim 1, wherein the dimming layer is disposed between the first anode and the first pixel defining layer or on the first cathode.

3. The display panel according to claim 1, wherein the dimming layer comprises a transparent opening disposed corresponding to the first opening.

4. The display panel according to claim 1, wherein the display region comprises:
a second anode;
a second pixel defining layer, the second pixel defining layer including a second opening exposing the second anode;
a second light emitting material disposed on the second anode;
a second cathode disposed on the second light emitting material;
wherein the second cathode is electrically insulated from the first cathode.

5. The display panel according to claim 1, wherein the Bragg film comprises a first film and a second film which are alternately laminated, materials of the first film and the second film are different, and a refractive index of the first film is greater than a refractive index of the second film.

6. The display panel of claim 5, wherein the first film is silicon, and the second film is one of silicon oxide, aluminum oxide, and titanium oxide.

7. The display panel according to claim 1, wherein the first light emitting material is disposed in the first opening and is electrically connected to the first anode; the dimming layer is disposed between the first pixel defining layer and the first cathode.

8. A display panel, wherein the display panel comprises a substrate and a display region and a transparent display region disposed on the substrate;
wherein the transparent display region comprises:
a first anode;
a first pixel defining layer, the first pixel defining layer including a first opening exposing the first anode;
a first light emitting material disposed on the first anode;
a first cathode disposed on the first light emitting material; and
a dimming layer disposed on the first anode.

9. The display panel according to claim 8, wherein the dimming layer is disposed between the first anode and the first pixel defining layer or on the first cathode.

10. The display panel according to claim 8, wherein the dimming layer comprises a transparent opening disposed corresponding to the first opening.

11. The display panel according to claim 8, wherein the display region comprises:
a second anode;
a second pixel defining layer, the second pixel defining layer including a second opening exposing the second anode;
a second light emitting material disposed on the second anode;
a second cathode disposed on the second light emitting material;
wherein the second cathode is electrically insulated from the first cathode.

12. The display panel according to claim 8, wherein the dimming layer is a Bragg film.

13. The display panel according to claim 12, wherein the Bragg film comprises a first film and a second film which are alternately laminated, materials of the first film and the second film are different, and a refractive index of the first film is greater than a refractive index of the second film.

14. The display panel of claim 13, wherein the first film is silicon, and the second film is one of silicon oxide, aluminum oxide, and titanium oxide.

15. The display panel according to claim 8, wherein the first light emitting material is disposed in the first opening and is electrically connected to the first anode; the dimming layer is disposed between the first pixel defining layer and the first cathode.

16. An electronic device, wherein the electronic device comprises a display panel and a light sensing unit disposed under the display panel, the display panel comprises a substrate and a display region and a transparent display region disposed on the substrate;
wherein the transparent display region comprises:
a first anode;
a first pixel defining layer, the first pixel defining layer including a first opening exposing the first anode;
a first light emitting material disposed on the first anode;
a first cathode disposed on the first light emitting material; and
a dimming layer disposed on the first anode.

17. The electronic device according to claim 16, wherein the dimming layer is a Bragg film.

18. The electronic device according to claim 16, wherein a projection of the light sensing unit on a horizontal plane overlaps with a projection of the transparent display region on a horizontal plane.
